(19) United States
(12) Patent Application Publication
(10) Pub. No.: US 2025/0015552 A1
(43) Pub. Date: Jan. 9, 2025

(54) HIGH-POWER DIODE LASER SYSTEM

(71) Applicant: Raytum Photonics LLC, Sterling, VA (US)

(72) Inventors: Wei Lu, Great Falls, VA (US); Bo Guo, San Jose, CA (US); Yimin Hu, Clarksville, MD (US)

(73) Assignee: Raytum Photonics LLC, Sterling, VA (US)

(21) Appl. No.: 18/348,647

(22) Filed: Jul. 7, 2023

(51) Int. Cl. H01S 3/0941; H01S 3/10; H01S 5/40

(52) U.S. Cl. CPC H01S 3/09415; H01S 3/10023; H01S 5/4012

(57) ABSTRACT

The present application discloses a high-power diode laser system configured to generate scalable output power. The laser system comprises a plurality of diode lasers, a fiber beam combiner, and a controller. Each of the plurality of diode lasers is configured to generate an output laser beam. The fiber beam combiner is configured to output a combined laser beam by combining a plurality of output laser beams generated by the plurality of diode lasers. The controller is configured to tune each diode laser in the plurality of diode lasers to align a wavelength of each output laser beam in the plurality of output laser beams.

### ACKNOWLEDGMENT OF GOVERNMENT SUPPORT

This invention was made with government support under Contract No. DE-SC0017155 awarded by the U.S. Department of Energy. The government has certain rights in the invention.

### FIELD OF THE TECHNOLOGY

The present disclosure relates generally to a laser system, and more specifically to a high-power diode laser system with a time-distributed wavelength locking mechanism.

### BACKGROUND

High power lasers have demonstrated their capability to optically pump alkali metal vapor, such as cesium, potassium, and rubidium. One example of high-power lasers used for optical pumping is alkali gas laser. Another use of high-power lasers is for polarizing noble gases such as Helium-3 and Xenon-129 through a spin-exchange optical pumping (SEOP) process. During an SEOP process, a rubidium (Rb) vapor mixed with noble gas needs to be polarized first through optical pumping, which can be achieved using high power lasers with a circular polarization output.

High-power lasers have also found widespread use in fields such as directed energy, environmental monitoring, spectroscopy, and medical applications.

Several conventional techniques have been used to scale up a diode laser's output power. For example, one technique combines two diode lasers with a 90° polarization difference by using a polarization beam splitter in free space. Such an approach is limited in output power (only two lasers can be used) and requires careful control of polarization and beam propagation angle.

Another technique couples the output of individual diode lasers into a multimode fiber first and then uses a fiber bundle to combine the fiber-coupled diode lasers together. However, the problem with this approach is that the fiber bundle cannot separate the laser beams of different lasers, leading to a scattered output beam profile and making it difficult for an operator to focus the output laser beam. Moreover, individually adjusting the lasing wavelength of each laser is practically difficult, and the broadening of the overall linewidth is inevitable due to the challenges in trying to align the emission lines from different lasers to a same position. In practical applications where a laser system runs continuously for days or months, frequent wavelength checks and manual adjustments are inconvenient and pose significant operational obstacles.

There is a need for a high-power diode laser system that addresses the above-described problems in the prior art.

### SUMMARY

The present application discloses a high-power diode laser system configured to lock the laser system to a system wavelength automatically and generate an output high-power laser beam of a scalable output power and narrow bandwidth.

In some embodiments, a laser system is configured to generate a scalable output power. The laser system comprises a plurality of diode lasers, a fiber beam combiner, and a controller. In the plurality of diode lasers, each is configured to generate an output laser beam. The fiber beam combiner is configured to output a combined laser beam by combining a plurality of output laser beams generated by the plurality of diode lasers. The controller is configured to tune each diode laser in the plurality of diode lasers to align the wavelength of each output laser beam in the plurality of output laser beams.

In some embodiments, the controller comprises a fiber switch, a wavelength sensor, and a control processor. The fiber switch is configured to collect a light sample from each diode laser and output the collected light sample from each diode laser in a time sequence. The wavelength sensor is configured to receive the collected light sample of each diode laser from the fiber switch in the time sequence and measure a wavelength deviation for each diode laser. The control processor is configured to control each diode laser in the plurality of diode lasers to adjust the wavelength of each output laser beam in the plurality of output laser beams based on the wavelength deviation measured by the wavelength sensor.

In some embodiments, the fiber beam combiner includes multiple input ports. Each input port is coupled with a diode laser in the plurality of diode lasers. The output power of the laser system is a combination of an output power of each diode laser.

In some embodiments, the fiber switch comprises a micro-electro-mechanical system (MEMS) optical switch. The MEMS optical switch is configured to transmit to the wavelength sensor in each time period (e.g., a time-distributed period in the time sequence) the collected light sample from each diode laser, in the time sequence.

In some embodiments, the fiber switch further comprises collimators and lenses to control a path of the collected light sample from each diode laser.

In some embodiments, each diode laser comprises a volume Bragg grating (VBG) device. A VBG device is characterized by a Bragg wavelength and is configured to selectively amplify a light beam inside the diode laser at the Bragg wavelength to lock the diode laser at the Bragg wavelength. In one embodiment, the VBG device is configured with a cavity and the cavity reflects back only the light beam of the Bragg wavelength, thereby filtering out other wavelengths.

In some embodiments, the Bragg wavelength is temperature-sensitive and the VBG device comprises a heater that is controlled by the controller to adjust the temperature of the VBG device. In this way, the temperature of the VBG device is kept constant and the Bragg wavelength is locked to the same position. In one embodiment, the controller is configured to tune each diode laser in the plurality of diode lasers to align a wavelength of each output laser beam in the plurality of output laser beams to a same position. The controller achieves the alignment by controlling the temperature of the VBG device in each diode laser so that each diode laser is locked to an approximately same wavelength. In one embodiment, the temperature of the VBG device is controlled by a temperature control device, which is configured to increase and/or decrease the temperature of the VBG device.

In some embodiments, the wavelength sensor of the controller comprises a collimator, a diffraction grating lens and a focusing lens. The collected light sample from each diode laser passes through the collimator, the diffraction grating lens and the focusing lens. The light sample is then focused on a position sensor. In one embodiment, the position sensor detects the position of the focused light, and the deviation in wavelength of the light sample is determined based on a position deviation of the focused light.

In one embodiment, the position sensor is configured to mark a central position that corresponds to a locked wavelength, measure a distance between the central position and the position of the focused light, and convert the measured distance into a wavelength deviation.

In some embodiments, the controller is configured to determine a temperature adjustment of the VBG device in each diode laser based on the wavelength deviation. The temperature adjustment is proportional to the wavelength deviation.

In some embodiments, a time distributed fiber switch is disclosed. The disclosed time distributed fiber switch may be used in a high-power diode laser system disclosed herein. The time distributed fiber switch comprises a plurality of input ports, a collimator, an optical switch, and a focusing lens. The input ports are configured to receive a plurality of input light beams respectively. The collimator is configured to collimate the plurality of input light beams. The optical switch is configured to sequentially select an input beam from the plurality of collimated input light beams and direct the selected input beam towards the focusing lens. The time distributed fiber switch generates an output light beam derived from the input of each input port in a time distributed manner. In one embodiment, the optical switch is a MEMS.

In some embodiments, a method of tuning a high-power laser system is disclosed. The high-power laser system comprises a plurality of diode lasers and a controller. The plurality of diode lasers are configured to generate a plurality of laser beams, and each diode laser comprises a temperature control device. The controller comprises a wavelength sensor. In the laser system tuning method, a light sample is collected from a first laser beam in the plurality of laser beams, the first laser beam being generated by a first diode laser. A wavelength deviation from a desired wavelength is detected by the wavelength sensor in the collected light sample from the first laser beam. The controller determines a temperature adjustment based by the wavelength deviation and controls the temperature control device to adjust a temperature of the first diode laser based on the temperature adjustment. With the temperature adjustment, the wavelength of the first laser beam from the first diode laser is corrected by the wavelength deviation. The adjusted wavelength of the first laser beam matches or approximates the desired wavelength. These steps are then performed for each diode laser in the plurality of diode lasers in time sequence, to align the plurality of laser beams to the desired wavelength.

In some embodiments, a laser system configured to generate a scalable output power is disclosed. The laser system comprises a plurality of diode lasers, a fiber beam combiner and a controller. Each of the plurality of diode lasers is configured to generate an output laser beam. The fiber beam combiner is configured to output a combined laser beam by combining a plurality of output laser beams generated by the plurality of diode lasers. The controller is configured to tune each diode laser in the plurality of diode lasers to align the wavelength of each output laser beam in the plurality of output laser beams to a desired wavelength.

In one embodiment, each diode laser comprises a volume Bragg grating (VBG) device. The VBG device is configured to lock a Bragg wavelength of the diode laser to a pre-determined value. The Bragg wavelength of a VBG device is temperature sensitive. The VBG device comprises a heater controlled by the controller to adjust the temperature of the VBG device. By adjusting the temperature of the VBG device in each diode laser, the controller tunes each diode laser to align the wavelength of each output laser beam to a desired value so that each diode laser is locked to an approximately same wavelength.

### BRIEF DESCRIPTION OF THE DRAWINGS

These and other features of the present disclosure will become readily apparent upon further review of the following specification and drawings. In the drawings, like reference numerals designate corresponding parts throughout the views. Moreover, components in the drawings are not necessarily drawn to scale, and the emphasis instead being placed upon clearly illustrating the principles of the present disclosure.

FIG. 1 is a block diagram of an embodiment of the high-power diode laser system disclosed in the present application.

FIG. 2 is an illustration of an embodiment of a volume-Bragg grating (VBG) diode laser.

FIG. 3 is an illustration of an example switch disclosed in an embodiment of the present application.

FIG. 4(a) illustrates a wavelength-deviation detection device described in an embodiment of the present application.

FIG. 4(b) illustrates another wavelength-deviation detection device described in an embodiment of the present application.

FIG. 5(a) is a block diagram of a controller described in an embodiment of the present application.

FIG. 5(b) illustrates a feedback loop of the high-power diode laser system disclosed in the present application.

FIG. 6 is a flow chart illustrating a control process of the high-power diode laser system described in an embodiment of the present application.

FIG. 7 illustrates charts reflecting a laser beam of a VBG laser being locked to the Bragg wavelength.

FIG. 8 illustrates a chart reflecting a tuning process of an output laser beam of the high-power diode laser system disclosed in an embodiment of the present application.

### DETAILED DESCRIPTION

Embodiments of the disclosure are described more fully hereinafter with reference to the accompanying drawings, in which preferred embodiments of the disclosure are shown. The various embodiments of the disclosure may, however, be embodied in many different forms and should not be construed as limited to the embodiments set forth herein. Rather, these embodiments are provided so that this disclosure will be thorough and complete, and will convey the scope of the disclosure to those skilled in the art.

One typical use of a high-power laser to is to pump an alkali vapor atom from a lower energy level to a high energy level, which is also known as optical pumping. The absorption spectrum of an alkali vapor atom is typically narrow, which means only a laser beam with a precise wavelength that matches the absorption spectrum can be absorbed by alkali vapor atoms. A small deviation in the laser wavelength of the laser beam can result in a significant reduction in absorption efficiency. Therefore, a high-power laser with a narrow lasing linewidth that matches the absorption line of the vapor gas is desirable in an optical pumping device.

To this end, semiconductor diode lasers may be selected for optical pumping, as they offer greater reliability and lower cost than other types of lasers. Further, volume-Bragg grating (VBG) devices have been utilized in semiconductor diode lasers to narrow the linewidth of a diode laser and to lock the lasing wavelength to match the alkali vapor absorption line. However, the wavelength locked by a VBG is dependent on the temperature of the device. For instance, in some VBG devices, the wavelength shifting rate over temperature is about 0.1 nm/15° C. During use, the laser beam will heat up the VBG when the laser beam passes through the device. When the laser power increases by 30 Watts, the temperature of the VBG device will rise by about 20° C. To prevent the wavelength of the VBG device from shifting away from the alkali vapor absorption line, it is desirable to maintain a stable temperature for laser operation.

Further, the position of the alkali vapor gas absorption line shifts with environmental changes such as changes in noble gas density or ambient temperature. This can also significantly affect the polarization efficiency. To compensate temperature changes as well as environmental changes, a chirped VBG device may be used to manually align the diode laser emission wavelength. Alternatively, the temperature of a VBG device may be uniformly changed to match the alkali gas absorption line.

The present application discloses a high-power laser system that can automatically align the wavelength of multiple VBG devices and lock the wavelength of the multiple VBG devices so the wavelength of output laser beams is not affected by temperature shifts or other environmental changes. The high-power laser system disclosed herein is also scalable in output power when individual diode lasers are integrated to output a combined laser output beam with a locked wavelength.

It is noted that in the present disclosure, VBG devices are used as an example to illustrate the principles and concepts of the methods and apparatus disclosed herein. Diode laser devices incorporating devices similar to or different than VBG devices can be used as alternatives in the methods and apparatus described herein and are within the scope of the present disclosure. Further, diode lasers are used as illustrative examples and can be substituted with other types of lasers without deviating from the principles and concepts disclosed herein.

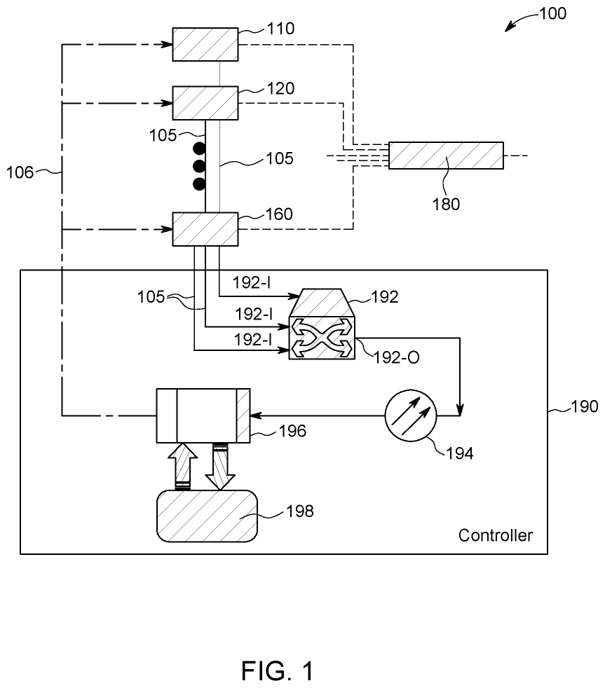

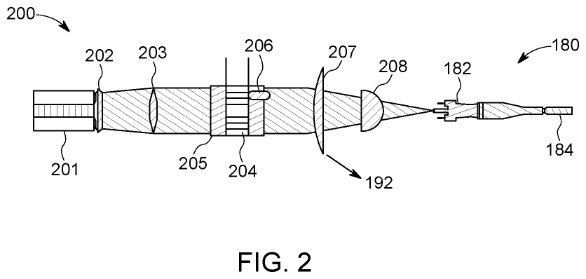

In referring to FIG. 1, a high-power laser system 100 is shown to comprise a plurality of diode lasers (110, 120, . . . , 160), a fiber beam combiner 180, and a controller 190. The fiber beam combiner 180 combines the output of a plurality of diode lasers 110, 120, . . . , 160 to generate an output that combines the output laser beams from the plurality of diode lasers. The fiber beam combiner 180 is configured with multiple input ports 182 (see FIG. 2). Each input port is coupled with a diode laser 110, 120, . . . , or 160, to receive an input laser beam output from a diode laser. The fiber beam combiner 180 is also configured with an output port 184 (see FIG. 2) to output one laser beam that combines the plurality of input laser beams. The output power of the fiber beam combiner 180 is proportional to the number of diode lasers. By adjusting the number of diode lasers, the output of the laser system 100 becomes scalable.

The laser system further combines a controller 190. The controller 190 includes a fiber switch 192, a wavelength sensor 194 and a control processor 196. The fiber switch 192 is configured to collect a light sample from each diode laser 110, 120, . . . , or 160 via a fiber 105. In one implementation, a small fraction of the output light from each diode laser is collected and redirected to an input port 192-I of the fiber switch 192.

In some embodiments, the fiber switch 192 is configured to output from an output port 192-O the light sample collected from each diode laser sequentially. The output light from the fiber switch 192 is input into the wavelength sensor 194.

In some embodiments, the wavelength sensor 194 measures the wavelength of the output light from the fiber switch 192. In one embodiment, the wavelength sensor 194 is configured to measure a deviation of the wavelength of the output light as compared to a benchmark, such as a desired wavelength of the output laser beam of the fiber beam combiner. For example, the desired wavelength matches the absorption line of alkali vapor atoms.

The wavelength information generated by the wavelength sensor 194 is input into the control processor 196. The control processor 196 may further comprise a control unit 198 (such as a module or processor or circuit) configured to convert the wavelength information or wavelength deviation information into control information. The control information is then fed back via a feedback loop 106 for tuning the plurality of diode lasers 110, 120, . . . , 160 and aligning the wavelength of the output lase beam from each diode laser.

FIG. 2 illustrates an example diode laser 200. The diode laser 200 includes a VBG device 204. A VBG device is generally characterized by a Bragg wavelength. The VBG device 204 is designed to amplify the Bragg wavelength and filter out other wavelengths.

In the VBG device 204 shown in FIG. 2, the short horizontal lines represent a grating structure. When a light beam passes through the VBG device 204, the VBG device 204 experiences a strong Bragg reflection at the wavelength that matches the grating period (i.e., distance between two adjacent gratings). This reflection effect enables the VBG 204 to act as a narrowband filter that transmits light only at the specific wavelength. When a laser is coupled into a VBG device 204, the VBG 204 reflects the light at the Bragg wavelength into the laser cavity. This process selectively amplifies the lasing mode that matches the Bragg wavelength and suppresses other modes. As a result, the laser 200 is locked to the Bragg wavelength and outputs a laser beam having a narrow spectral width determined by the VBG wavelength.

The Bragg wavelength can be expressed as:

$${λ}_{B} = 2 \times {n}_{eff} \times Λ , \qquad Equation ( 1 )$$

where λ_{B} is the Bragg wavelength, n_{eff} is the effective refractive index of the VBG device 204, and A is the period of the grating structure. The spectral width of the output beam can be expressed as:

$${Δ}_{λ} = {λ}_{B} \times {Δ}_{n} / {n}_{avg} , \qquad Equation ( 2 )$$

where Δ_{λ} is the spectral width (full-width at half-maximum (FWHM)) of the VBG device 204, Δₙ is the refractive index modulation depth of the VBG 204, and n_{avg} is the average refractive index of the grating structure. When the temperature of the VBG device 204 changes, the grating period Λ changes with the temperature, resulting in a shift of the Bragg wavelength. Typically, at a nominal wavelength of 795 nm, the wavelength changes with the temperature at the rate of about 0.1 nm/15° C. The shift of the Bragg wavelength also leads to the change of the spectral width, and the changing rate of the spectral width is proportional to the percentage change of the Bragg wavelength. Typically, the Bragg wavelength shifts by approximately 0.1% at the nominal wavelength. As such, the change (i.e., broadening) of the spectral width is often negligible. It is generally assumed that the laser spectral width remains unchanged during the laser operation.

As shown in FIG. 2, a broad area heater 205 is placed underneath the VBG device 204. The heater 205 is configured to control the temperature of the VBG device 204. In an example VBG device 204, the higher the temperature of the VBG device 204 is set, the longer the Bragg wavelength becomes, and vice versa.

FIG. 2 further shows the internal structure of the laser 200 as comprising a diode bar 201, a fast axis collimator 202, a slow axis collimator 203, a VBG device 204, a broad area heater 205, a temperature sensor 206, and a series of lenses 207, 208, etc. The laser 200 is connected to a fiber switch 180 via one of the input ports 182 of the fiber switch 180. The fiber switch 180 is also configured with an output port 184.

The output beam of the laser diode bar 201 is collimated by the fast axis collimator 202 and the slow axis collimator 203. The collimated beam passes through the VBG device 204. By changing the driving current in the heater 205, it is feasible to adjust the temperature of the heater 205 and that of the VBG device 204. The temperature of the VBG device 204 is monitored by the temperature sensor 106. The driving current of the heater 205 is controlled by the controller 190 (see FIG. 1). After passing through the VBG device 204, the collimated laser beam is further focused by a series of lenses 107 and 108 and then coupled into the input fiber of the fiber beam combiner 180 via the input ports 182. The fiber switch 180 combines a plurality of laser beams from the input ports 182 and outputs a combined high-power laser beam from the output port 184.

Fiber beam combiners such as the combiner 180 are widely used in high-power fiber laser industry. To fabricate a fiber beam combiner, multiple fibers of a large diameter, e.g., 400 μm, are bundled together. These fibers are molded into one large piece when heated up to a relatively high temperature (e.g., higher than 1000° C.). The combined fiber is gradually tapered down to a size that matches the output fiber and is then spliced with an output fiber.

For a typical fiber beam combiner, the size of an input fiber is approximately 400 μm. A typical structure of a high-power fiber beam combiner may be 4×1 (4 inputs and 1 output), 5×1 (5 inputs and 1 output as shown in FIG. 1), and 7×1 (7 inputs and 1 output). In some cases, the number of input ports can be as high as 26. The output fiber size increases as the number of input ports increases. For example, for a 4×1 fiber combiner, the output fiber size is approximately 800 μm, while for a 26×1 combiner, the output fiber size is approximately 1.5 mm, which is almost twice as large. The transmission efficiency of a fiber beam combiner generally is considered sufficiently for general purposes. For a 4×1 fiber combiner, the transmission efficiency is above 95%. The transmission efficiency decreases as the number of input ports increases. For a 26×1 fiber beam combiner, the transmission efficiency can still be above 80%. Fiber beam combiners have advantages over free space polarization beam combining techniques, not only because it can handle many more input ports (as described in the Background section, the free space polarization combining technique can only handle two inputs), but also because fiber beam combiners are much easier to use and maintain. In some embodiments, more than 1 kW output power can be achieved by using a 26×1 fiber beam combiner. Such a high-power laser beam is a powerful tool for polarizing either noble gases such as ³He or ¹²⁹Xe.

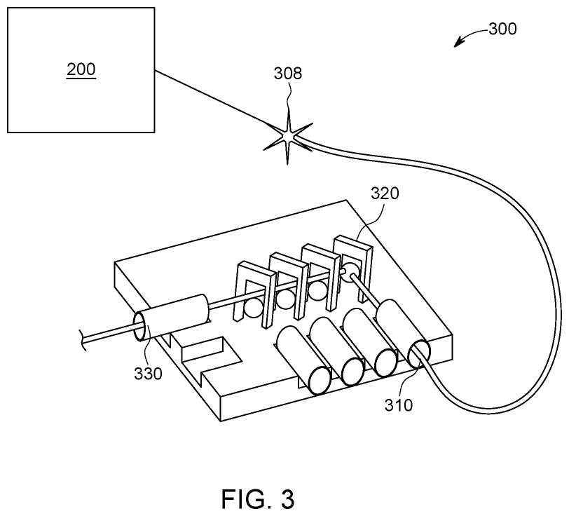

In FIG. 2, a light sample from the lens 207 is collected and directed to the fiber switch 192. The power of the laser beam from the diode bar 201 is relatively high in Watt level, for example, as high as 60 W. Therefore, there is significant scattering out of the optics components such as the lens 207, 208, etc., and the gratings in the VBG device 204. The scattered light can be collected by a fiber 308 as light sample and transported to the fiber switch 300 (see FIG. 3). The power of the scattered light is low, for example, in the micro-Watts level, but would be sufficient for the fiber switch 300 to function.

FIG. 3 illustrates an example fiber switch 300. The fiber switch 300 in FIG. 3 is a 4×1 fiber switch. In other embodiments, the number of input ports on a fiber switch can be more than four. The number of input ports at the fiber switch 300 generally matches with the number of input ports at the beam combiner 180, for example, 4, 5, 7, or up to 26. The scattered light collected by an input fiber of the fiber switch 300 is collimated by a collimator (not shown) before being transmitted to an optical switch 320.

The fiber switch 300 in FIG. 3 comprises an input fiber 308, four input ports 310, four optical switches 320, one output port 330. The input fiber 308 connects the diode laser 200 to one of the four input ports 310 to conduct the sample light collected from the diode laser 200 to the optical switch 320. In some embodiments, the four optical switches 320 in the fiber switch 300 may be implemented as a Micro-Electromechanical (MEMS) optical switch.

A MEMS optical switch comprises an array of tiny lenses engraved on a silicon crystal. The micro mirror array is rotated through the action of an electrostatic force or an electromagnetic force. The rotation of each mirror in the micro mirror array is controlled individually to change the propagation direction of each input light beam. By diverting a particular input light beam away from the output port 330, the optical path of the input light beam can be turned off. The optical path can be turned back on when the mirror in the micro mirror array is adjusted to reflect the input light beam towards the output port 330. The MEMS optical switch is controlled by the control processor 196 (see FIG. 1).

In some embodiments, only one mirror (as referred to as channel) in the MEMS optical switch is situated at the right angle to direct the corresponding input beam to the output port at any time. The angles of the mirrors in the other channels are such that the optical paths of these channels are turned off. Therefore, the MEMS fiber switch is configured to output spectral information one channel at a time. However, the present disclosure is not limited to the use of MEMS-based fiber switch. Other types of fiber switch, such as thermo-optic switch, electro-optic switch, and acousto-optic optical switch can also be used in the methods and apparatus disclosed herein.

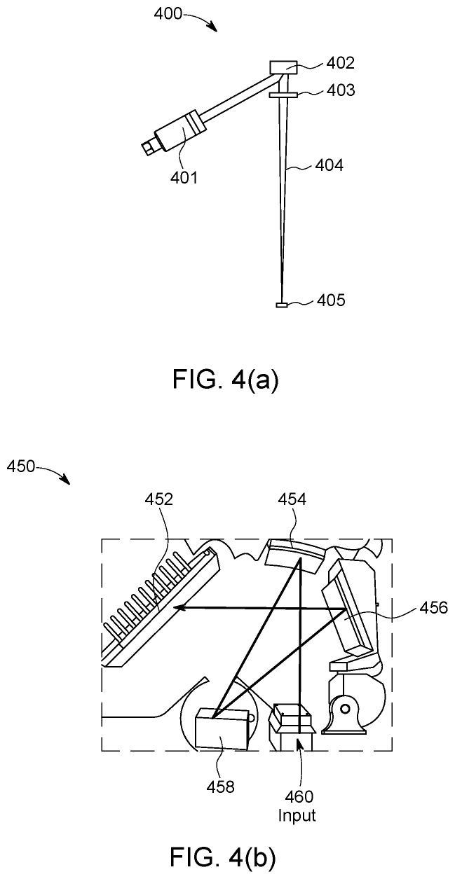

The output of the fiber switch 300 is input into a wavelength sensor 400. See FIG. 4(a) and FIG. 4(b). Also see FIG. 1 showing the output of the fiber switch 192 is collected by a wavelength sensor 194. FIG. 4(a) and FIG. 4(b) illustrate two embodiments of the wavelength sensor 194.

FIG. 4(a) illustrates the structure of an example wavelength sensor 400. Light sample of a diode laser 200 is collected by a fiber 308 and then collimated by a collimator 401. The collimated beam is reflected by a grating 402 and focused by a lens 403. The focused beam 404 is detected by a position sensor 405. In one embodiment, the laser beam 404 with the nominal wavelength (e.g. 794.7 nm) hits the center of the position sensor 405. A slight change in the wavelength will cause a corresponding shift in the angle of the diffracted light from the grating 402. The shifted diffracted light 404, when being focused onto the position sensor 405 by the focusing lens 403, will hit an off-center position on the position sensor 405.

FIG. 4(b) illustrates another embodiment of a wavelength sensor 450. The optical wavelength sensor 450 comprises an input port 460, a first concave mirror 454, a second concave mirror 456, a grating 458, and a position sensor 452. An input beam from the input port 460 hits the first concave mirror 454 and becomes collimated after reflection. The collimated beam reaches the grating 458 and is diffracted. The diffracted beam is then directed to the second concave mirror 456. The second concave mirror 456 functions like a focusing lens. The light beam becomes focused after reflection from the second concave mirror 456 before reaching the position sensor 452. In this embodiment, concave mirrors instead of lenses are used to avoid excess material dispersions, which often affect the spectral measurement accuracy. In the wavelength sensor 450, different wavelengths are encoded into different positions inside the position detector 452. The output of the wavelength sensor 405 is transmitted to the controller 190 (see FIG. 1), which sends control signals to the plurality of diode lasers 110, 120, . . . , 160 to control the temperatures of the lasers via the heaters 205 (shown in FIG. 2).

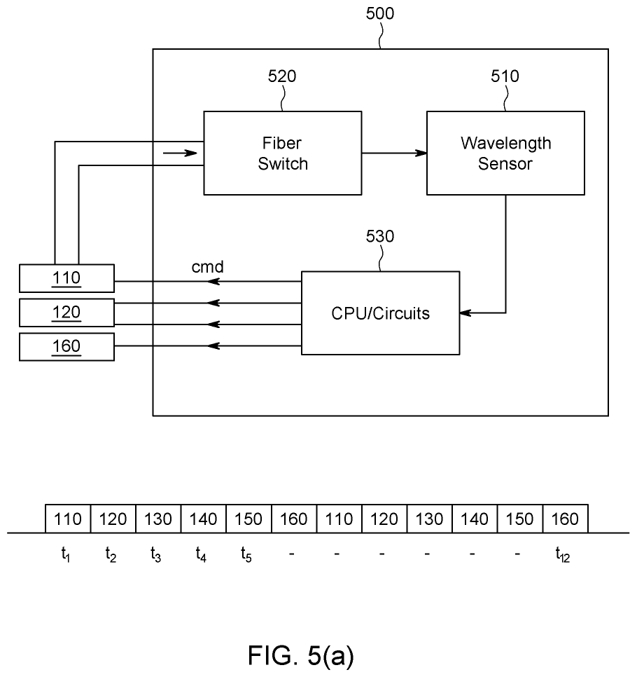

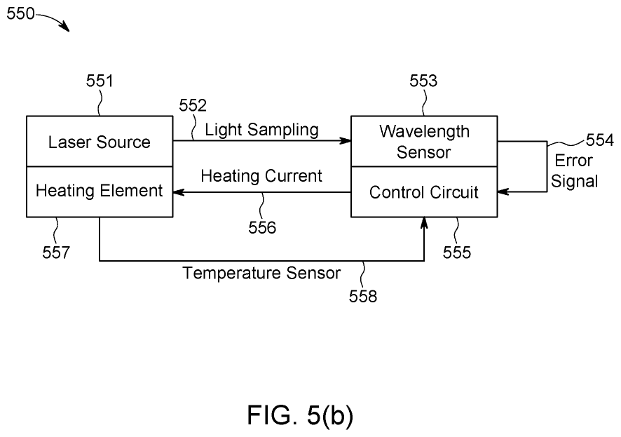

An example of the controller 190 is shown in FIG. 5(a). FIG. 5(a) illustrates a block diagram of a controller embodiment 500. As shown in FIG. 5(a), the controller 500 comprises a fiber switch 520, a wavelength sensor 510, and a control processor 530. In some embodiments, the control processor 530 is implemented as a control circuit board or a central processing unit (CPU) or processing circuits.

The fiber switch 520 receives the collected light samples from the plurality of diode lasers via its input ports. The optical switches (320 in FIG. 3) in the fiber switch 520 are configured to selectively direct one input light beam onto the output port in a time-distributed manner. That is, the collected light sample from one diode laser (110, 120, . . . , or 160) is selected sequentially as the output light beam of the fiber switch 520. For example, at time period t₁, the collected light sample from the diode laser 110 is output by the fiber switch 520. At time period t₂, the collected light sample for the diode laser 120 is output by the fiber switch 520. At time period t₃, the collected light sample for the diode laser 130 is output by the fiber switch 520. So on and so forth. The output light beam from the fiber switch 520 at a particular time period corresponds to one diode laser, i.e., the one whose scattered light is collected as the input light sample of the fiber switch 520.

The output light beam from the fiber switch 520 is sent to the wavelength sensor 510. The wavelength sensor 510 measures the wavelength or a wavelength deviation from the nominal wavelength, of the output light beam. In one embodiment, the measured wavelength of the output light beam is sent to the control processor 530 to determine the deviation between the measured wavelength and the nominal wavelength. In another embodiment, the wavelength sensor 510 obtains the wavelength deviation directly and outputs the deviation to the control processor 520. For example, the wavelength deviation corresponds to the distance between the position of the light beam and the center position on the position sensor 452.

In some embodiments, the nominal wavelength corresponds to the center position of the position sensor 452. The nominal wavelength represents the desired wavelength required in an optical pumping operation. That is, a laser beam of the nominal wavelength provides the excitation energy needed to pump atoms in a target gas from a low energy level to an excited energy level.

After obtaining the wavelength deviation of a diode laser (110, 120, . . . , or 160), the control processor 530 determines a temperature adjustment for this diode laser based on the wavelength deviation. The control processor 530 then sends a command to control the heater to perform the temperature adjustment.

FIG. 5(b) illustrate an example control loop 550 implemented in the high-power laser system 100. At the laser source 551, a light sample 552 from a channel is collected and the spectral information of the channel and the channel number are recorded. Such information is forwarded to the wavelength sensor 553. At the wavelength sensor 553, the lasing wavelength of the channel is derived from the spectral information and is compared to a preset value (e.g., the nominal wavelength). An error signal 554 is then generated after the comparison and sent to the control circuit 555 (e.g., control processor) to determine the temperature adjustment of the VBG device of that channel. The command to perform the temperature adjustment is then sent out by the control circuit 555 to the heating element 557 of the laser in the corresponding channel. In FIG. 5(b), a temperature sensor 558 collects temperature information of the laser source 551 and sends the collected temperature information to the control circuit 555 for use when calculating the temperature adjustment.

The steps in FIG. 5(b) are performed for every laser in the system to tune each laser and to align the wavelength of each laser with a desired wavelength. The collection of the spectral information is done for every channel in the N channels, and the spectra information of each channel is collected within a specific time, e.g., 10 seconds or a pre-configured value that an operator sets.

During each loop, every laser in the system is tuned to align its lasing wavelength with the preset value. Usually after several loops, the wavelength of all the lasers in the system are well aligned. During operation, any deviation of the lasing wavelength of a particular laser will be detected by the wavelength sensor 553 and corrected by the control circuit 555. This automatic real-time feedback adjustment mechanism aligns the wavelength of each laser in the high-power laser system to a desired wavelength and locks the wavelength of the high-power laser system to the desired wavelength. It is automatic and real-time, thus, eliminating the need of manual adjustment.

In one embodiment, a 200 W high-power laser system includes four individual diode modules (e.g., 110, 120, etc.), each connected to an input port of the fiber switch 192. The fiber switch 192 allows one channel or one signal from a specific laser module to pass through at a specific time period, for example, every ten seconds, while the other channels are blocked, ensuring that only the spectrum information of that particular laser module is fed to the wavelength sensor 194 to determine the lasing (i.e., current or working) wavelength of the particular laser module. The control processor 196 compares the lasing wavelength with the desired wavelength and provides a temperature error signal to the temperature control unit inside the laser module for VBG temperature adjustment. The temperature adjustment process continues for each and every laser module in the system until the lasing wavelength of each laser module matches or aligns with the desired wavelength. This time-distributed wavelength locking mechanism automatically locks the wavelength of the high-power laser system to the desired wavelength during operation.

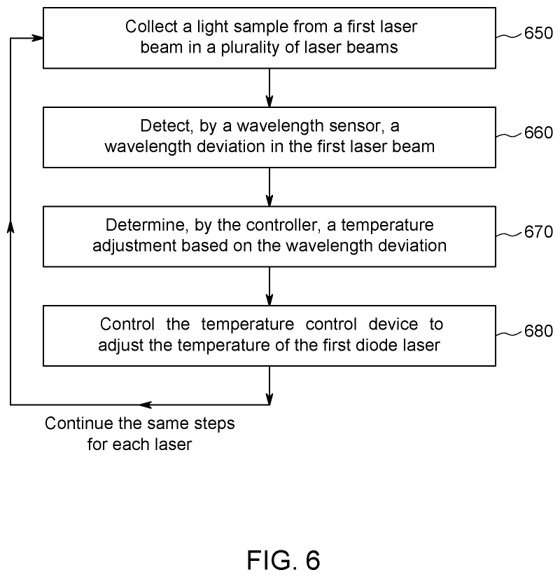

FIG. 6 illustrates a flow chart showing an example procedure in which the high-power laser system 100 tunes each diode laser 110, 120, . . . , 160, and locks the wavelength of the output laser beam of the laser system 100. The embodiment in FIG. 6 should not be construed as limiting, as the disclosed method steps can be performed separately, in different orders, or simultaneously, partially or completely with one another. Further, any of the disclosed methods or method steps in the present disclosure can be performed together with any other methods or method steps disclosed herein.

In FIG. 6, at step 650, a light sample is collected from a first laser beam in a plurality of laser beams. In one embodiment, a laser source, typically referred to as a laser diode bar (e.g., 201 in FIG. 2) or a laser diode array, outputs an output beam that is collimated by one or more collimators, for example, a fast axis collimator (e.g., 202 in FIG. 2) and a slow axis collimator (e.g., 203 in FIG. 2). The collimated laser beam passes through a series of optics components that includes a VBG device (e.g., 204 in FIG. 2) and one or more lenses (e.g., 207 and 208 in FIG. 2). The scattered light from an optics component (such as the VBG device or the lenses) is to be collected by a multimode fiber as a light sample of the laser source and transmitted to a wavelength senor (e.g., 194 in FIG. 1, 400 in FIG. 4(a), or 450 in FIG. 4(b)).

At step 660, the wavelength sensor detects a wavelength deviation in the first laser beam using the collected light sample. In one embodiment, the spectral information of the scattered light is retrieved or determined by a wavelength sensor 400 or 450 and compared with the desired wavelength. If there is any discrepancy, an error signal 554 is generated and sent to the control circuit 555.

At step 670, the controller (e.g., 190) determines a temperature adjustment based on the wavelength deviation contained in the error signal 554. At step 680, the controller (e.g., 190) controls a temperature control device (e.g., a heater 205) to adjust the temperature of the first diode laser 200. In one embodiment, according to the error signal 554 and the previous recorded temperature of the VBG device 204, the control circuit 555 sends a command to the heater 205 to generate a heating current inside the diode laser 200. The temperature of the VBG device 204 is adjusted due to the heating current and the new temperature information is recorded by the temperature sensor 558 and sent to the control circuit 555 to update the temperature record. In some embodiments, the heater 205 may be replaced by a cooling device or a temperature control device that can adjust the temperature up or down.

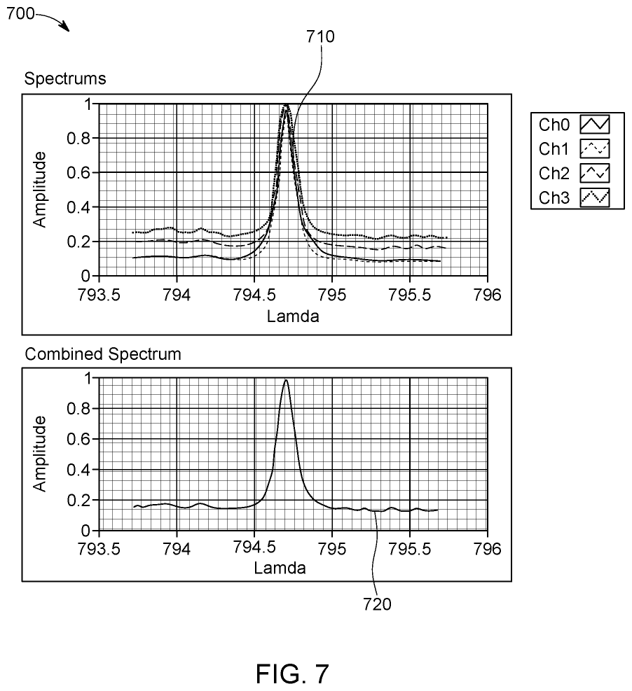

Laser systems disclosed herein are highly scalable because of the fiber optic combiner 180. A large core fiber optic combiner can support input ports up to 26 with fiber sizes as small as 400 μm. The total power output of a laser system disclosed herein can exceed 1 kW in principle, with a typical diode laser module delivering an output power of more than 50 W. In one embodiment, a laser system with four input ports was tested and achieved a 200 W output power. The present disclosure teaches a power scalable diode laser system that integrates individual high-power diode modules with wavelength locking and automatic alignment of lasing wavelengths. For instance, FIG. 7 shows the spectrum of an example laser system 700 that combines four individual laser modules (Ch0, Ch1, Ch2, and Ch3). FIG. 7 plots the amplitude of a laser beam (individual and combined) against the wavelength Lamda. The spectrum 710 from each of the four channels is locked in the same position at wavelength 794.65 μm. The combined spectrum 720 is locked at the same wavelength, 794.65 μm, and shows the same spectral width as that of the spectrum 710, of about 0.14 nm. The combined spectrum 720 does not show broadening because the lasing wavelength of each channel is locked in the same position.

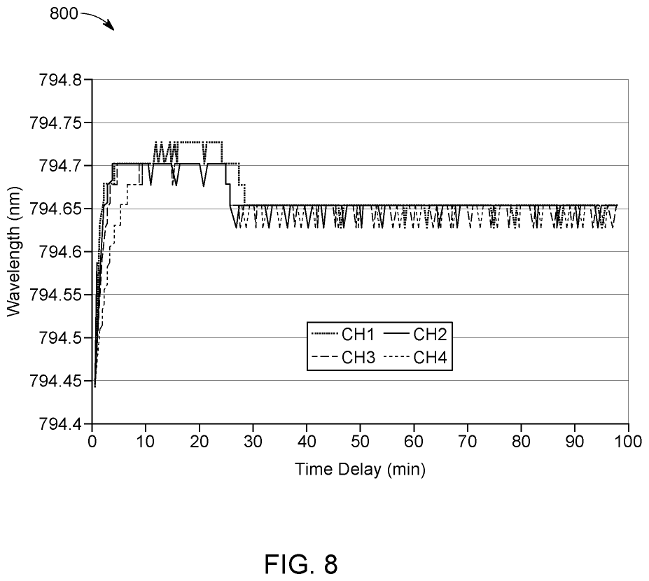

FIG. 8 shows a long-term testing process 800 of an example laser system 100 that combines four individual laser modules (CH1, CH2, CH3, and CH4). The wavelength of the output laser beam from each laser module is plotted against time over a period of 100 minutes. As shown in FIG. 8, it takes about 25 minutes to lock all four channels to the same position (e.g., same wavelength at 794.65 μm). After being locked, the system 100 experiences a 0.025 nm offset every 5 minutes, which is detected and automatically corrected by the system 100.

Although the disclosure is illustrated and described herein with reference to specific embodiments, the disclosure is not intended to be limited to the details shown. Rather, various modifications may be made in the details within the scope and range of equivalents of the claims and without departing from the disclosure.

What is claimed is:

1. A laser system configured to generate a scalable output power, comprising:
a plurality of diode lasers, each configured to generate an output laser beam;
a fiber beam combiner, configured to output a combined laser beam by combining a plurality of output laser beams generated by the plurality of diode lasers; and
a controller, configured to tune each diode laser in the plurality of diode lasers to align a wavelength of each output laser beam in the plurality of output laser beams, wherein the controller comprises:
a fiber switch configured to collect a light sample from each diode laser and output the collected light sample from each diode laser in a time sequence;
a wavelength sensor configured to receive the collected light sample of each diode laser from the fiber switch in the time sequence and measure a wavelength deviation for each diode laser; and
a control processor configured to control each diode laser in the plurality of diode lasers based on the wavelength deviation measured by the wavelength sensor to adjust the wavelength of each output laser beam in the plurality of output laser beams.

2. The laser system of claim 1, wherein the fiber beam combiner includes multiple input ports and each input port is coupled with a diode laser of the plurality of diode lasers, and wherein an output power of the laser system is a combination of an output power of each diode laser.

3. The laser system of claim 1, wherein the fiber switch comprises a micro-electro-mechanical systems (MEMS) optical switch.

4. The laser system of claim 1, wherein the MEMS optical switch is configured to transmit, to the wavelength sensor in a time-distributed period in the time sequence, the collected light sample from a diode laser of the plurality of diode lasers, and wherein the collected light sample from each of the plurality of diode lasers is transmitted in the time sequence to the wavelength sensor.

5. The laser system of claim 3, wherein the fiber switch further comprises collimators and lenses to control a path of the collected light sample from each diode laser.

6. The laser system of claim 1, wherein each diode laser comprises a volume Bragg grating (VBG) device and wherein the VBG device is characterized by a Bragg wavelength and is configured to selectively amplify a light beam inside the diode laser at the Bragg wavelength to lock the diode laser at the Bragg wavelength.

7. The laser system of claim 6, wherein the VBG device is configured to reflect back the light beam at the Bragg wavelength and filter out other wavelengths.

8. The laser system of claim 7, wherein the Bragg wavelength is temperature-sensitive and the VBG device comprises a heater controlled by the controller to adjust a temperature of the VBG device.

9. The laser system of claim 8, wherein the controller is configured to tune each diode laser in the plurality of diode lasers to align a wavelength of each output laser beam in the plurality of output laser beams by:
adjusting the temperature of the VBG device in each diode laser so that each diode laser is locked to an approximately same wavelength.

10. The laser system of claim 9, wherein the wavelength sensor comprises a collimator, a diffraction grating lens and a focusing lens;
wherein the collected light sample from each diode laser passes through the collimator, the diffraction grating lens and the focusing lens, and is focused on a position sensor; and
wherein the position sensor detects a position of the focused light, and the wavelength deviation is determined based on a position deviation of the focused light.

11. The laser system of claim 10, wherein the controller is configured to determine a temperature adjustment of the VBG device in each diode laser based on the wavelength deviation.

12. The laser system of claim 11, wherein the temperature adjustment is proportional to the wavelength deviation.

13. The laser system of claim 12, wherein the position sensor is configured to:
mark a central position that corresponds to a locked wavelength;
measure a distance between the central position and the position of the focused light; and
convert the measured distance into the wavelength deviation.

14. A time distributed fiber switch, comprising:
a plurality of input ports for receiving a plurality of input light beams;
a collimator configured to collimate the plurality of input light beams;
an optical switch; and
a focusing lens;
wherein the optical switch is configured to select an input beam from the plurality of input light beams after being collimated and direct the selected input beam towards the focusing lens sequentially; and
wherein the time distributed fiber switch generates an output light beam derived from each input port in a time distributed manner.

15. The fiber switch of claim 14, wherein the optical switch is a MEMS.

16. A method of tuning a high-power laser system, wherein the high-power laser system comprises a plurality of diode lasers and a controller, wherein the plurality of diode lasers are configured to generate a plurality of laser beams, and each diode laser comprises a temperature control device, and wherein the controller comprises a wavelength sensor, comprising:
collecting a light sample from a first laser beam in the plurality of laser beams, wherein the first laser beam is generated by a first diode laser;
detecting, by the wavelength sensor, a wavelength deviation in the first laser beam from a desired wavelength;
determining, by the controller, a temperature adjustment based on the wavelength deviation;
controlling the temperature control device to adjust a temperature of the first diode laser based on the temperature adjustment; and
outputting the first laser beam by the first diode laser with a wavelength corrected by the wavelength deviation.

17. The method of claim 18, further comprising performing the steps of claim 18 for each diode laser in the plurality of diode lasers in a time sequence, to align the plurality of laser beams to the desired wavelength.

18. A laser system configured to generate a scalable output power, comprising:
a plurality of diode lasers, each configured to generate an output laser beam;
a fiber beam combiner, configured to output a combined laser beam by combining a plurality of output laser beams generated by the plurality of diode lasers; and
a controller, configured to tune each diode laser in the plurality of diode lasers to align a wavelength of each output laser beam in the plurality of output laser beams.

19. The laser system of claim 18, wherein each diode laser comprises a volume Bragg grating (VBG) device and wherein the VBG device locks a Bragg wavelength of the diode laser; wherein the Bragg wavelength is temperature-sensitive and the VBG device comprises a heater controlled by the controller to adjust a temperature of the VBG device; and wherein the controller is configured to tune each diode laser in the plurality of diode lasers to align a wavelength of each output laser beam in the plurality of output laser beams by adjusting the temperature of the VBG device in each diode laser so that each diode laser locks at an approximately same wavelength.
